(19) United States
(12) Patent Application Publication
(10) Pub. No.: US 2010/0181507 A1
(43) Pub. Date: Jul. 22, 2010

(54) ILLUMINATING DEVICE AND IMAGE READING APPARATUS

(75) Inventor: Hiroyuki MARUYAMA, Ishikawa (JP)

Correspondence Address: LOWE HAUPTMAN HAM & BERNER, LLP, 1700 DIAGONAL ROAD, SUITE 300, ALEXANDRIA, VA, 22314, US

(73) Assignee: PFU LIMITED, ISHIKAWA (JP)

(21) Appl. No.: 12/686,900

(22) Filed: Jan. 13, 2010

(30) Foreign Application Priority Data
Jan. 19, 2009 (JP) 2009-008956

(51) Int. Cl. H01L 31/16; H01J 61/52; H01J 13/32

(52) U.S. Cl. 250/552; 315/112; 315/113; 315/294

(57) ABSTRACT

An illuminating device includes: an LED device configured to irradiate light; a temperature detecting unit configured to detect a change in temperature of the LED device; and a unit configured to linearly change a drive current supplied to the LED device according to the change in temperature of the LED device.

### CROSS-REFERENCE TO RELATED APPLICATIONS

This application is based upon and claims the benefit of priority from Japanese Patent Application No. 2009-008956, filed Jan. 19, 2009, the entire contents of which are incorporated herein by reference.

### BACKGROUND OF THE INVENTION

1. Field of the Invention

The present invention relates to an illuminating device and an image reading apparatus. In particular, the present invention relates to an illuminating device and an image reading apparatus, in which an LED device emits light toward an object to illuminate the object.

2. Description of the Related Art

Conventionally known illuminating devices include an illuminating device, which is used as a backlight of a liquid-crystal display device or as a light source of an image reading apparatus and which uses an LED device as a light emitting device that emits light toward an illuminated object. For example, an image exposure apparatus described in Japanese Patent Application Laid-open No. S62-299360 has an array of many light emitting devices (LED devices) grouped into a plurality of blocks along an array direction, and a temperature detecting device provided for each of the blocks. In this apparatus, light emission amounts of the light emitting devices in the block corresponding to each temperature detecting device are controlled based on a detected amount obtained by the temperature detecting device, to suppress variation in illumination distribution due to a temperature difference between an end of the array of light emitting devices and the center of the array of light emitting devices.

Luminous efficiency of an LED device used in such an illuminating device varies with change in temperature of the LED device, for example, with change in pn-junction temperature (so-called junction temperature) of the LED device. In the image exposure apparatus described in the above Japanese Patent Application, a structure is disclosed in which light quantity is adjusted by controlling an emission time period of each light emitting device by performing the so-called PWM control, according to the temperature difference between the end and the center of the array of light emitting devices. However, suppression of such change in light quantity with a simpler structure has been desired.

### SUMMARY OF THE INVENTION

According to an aspect of the present invention, an illuminating device includes: an LED device configured to irradiate light; a temperature detecting unit configured to detect a change in temperature of the LED device; and a unit configured to linearly change a drive current supplied to the LED device according to the change in temperature of the LED device.

According to another aspect of the present invention, an image reading apparatus includes the illuminating device, and a line sensor that includes a plurality of pixels that are arrayed in a main-scanning direction and that is configured to convert reflected light that has been emitted from the illuminating device and reflected from an illuminated object to an electrical signal to read an image from the illuminated object.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram of a configuration of an illuminating device according to an embodiment of the present invention;

FIG. 2 is a schematic perspective view of an image reading apparatus to which the illuminating device according to the embodiment of the present invention has been applied;

FIG. 3 is a schematic diagram of a configuration of the image reading apparatus to which the illuminating device according to the embodiment of the present invention has been applied;

FIG. 4 is a diagram for explaining a relationship between an LED-device temperature and an LED-device light quantity when a current and a voltage supplied to an LED device of the illuminating device according to the embodiment of the present invention are made constant;

FIG. 5 is a diagram for explaining a relationship between an LED-device light-quantity attenuation rate and an LED-device temperature change rate when the current and the voltage supplied to the LED device of the illuminating device according to the embodiment of the present invention are made constant;

FIG. 6 is a diagram for explaining the LED-device temperature change rate at each predetermined drive current when the voltage supplied to the LED device of the illuminating device according to the embodiment of the present invention is made constant;

FIG. 7 is a schematic perspective view of an example of a substrate (with the LED devices in parallel connection) of the illuminating device according to the embodiment of the present invention;

FIG. 8 is a schematic perspective view of an example of the substrate (with the LED devices in series connection) of the illuminating device according to the embodiment of the present invention;

FIG. 9 is a schematic cross-sectional view of an example of the substrate (with the LED devices in series connection) of the illuminating device according to the embodiment of the present invention;

FIG. 10 is a diagram for explaining variation in luminance of the LED device of the illuminating device according to the embodiment of the present invention;

FIG. 11 is a diagram of a specific example of a configuration of an analog circuit of the illuminating device according to the embodiment of the present invention; and

FIG. 12 is a diagram of another specific example of a configuration of the analog circuit of the illuminating device according to the embodiment of the present invention.

### DETAILED DESCRIPTION OF THE PREFERRED EMBODIMENTS

Exemplary embodiments of an illuminating device and an image reading apparatus according to the present invention will be explained in detail below with reference to the accompanying drawings. The present invention is not limited to the embodiments explained below. In addition, constituent elements in the following embodiments include those that are replaceable or easily replaced by persons skilled in the art or those substantially equivalent.

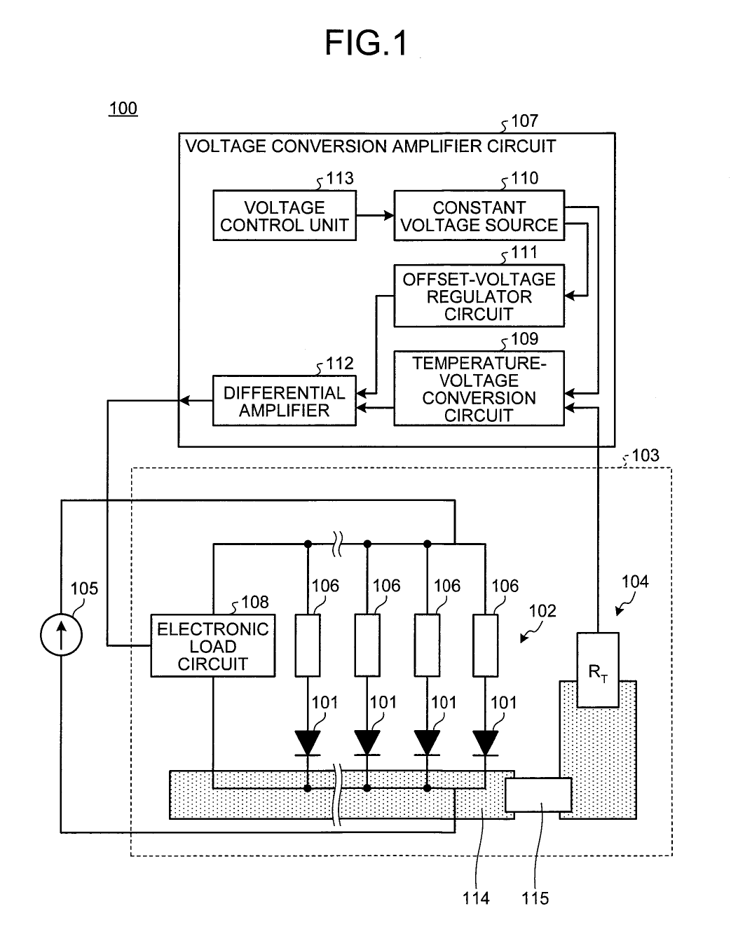

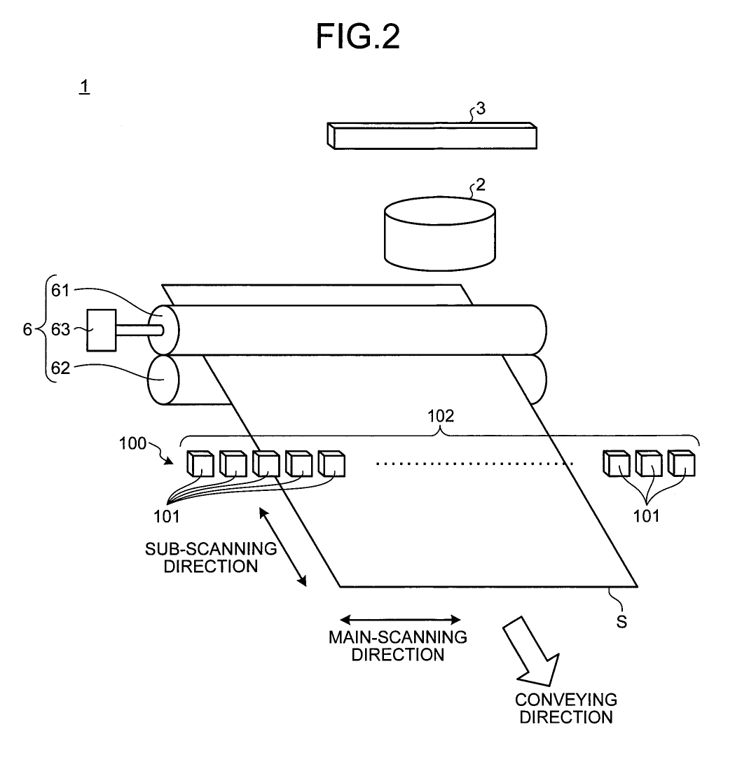

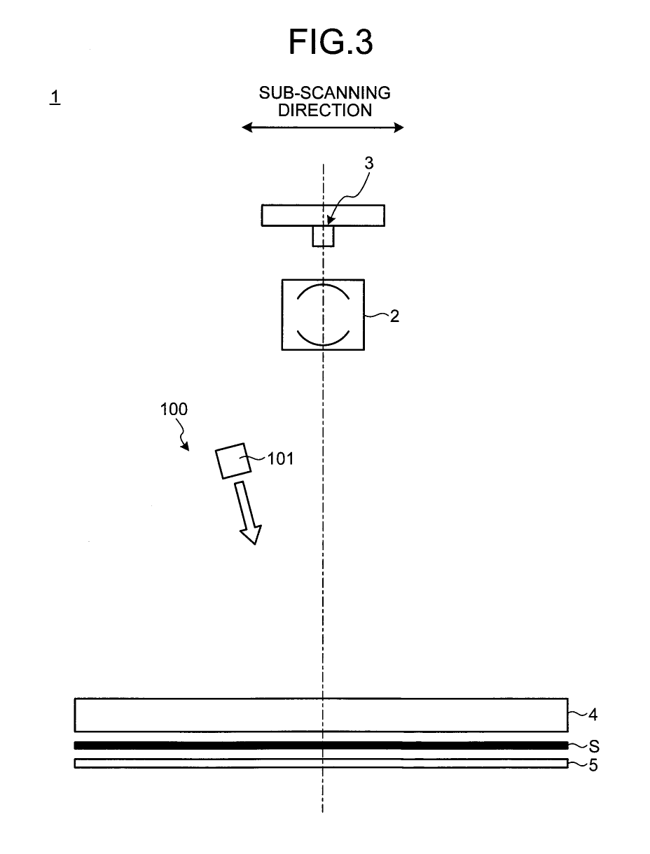

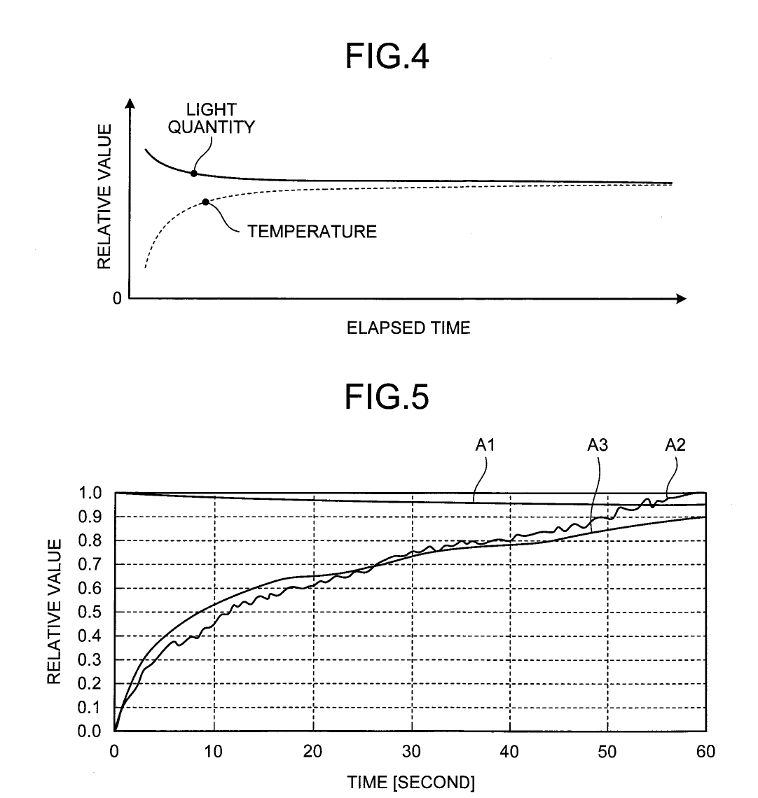

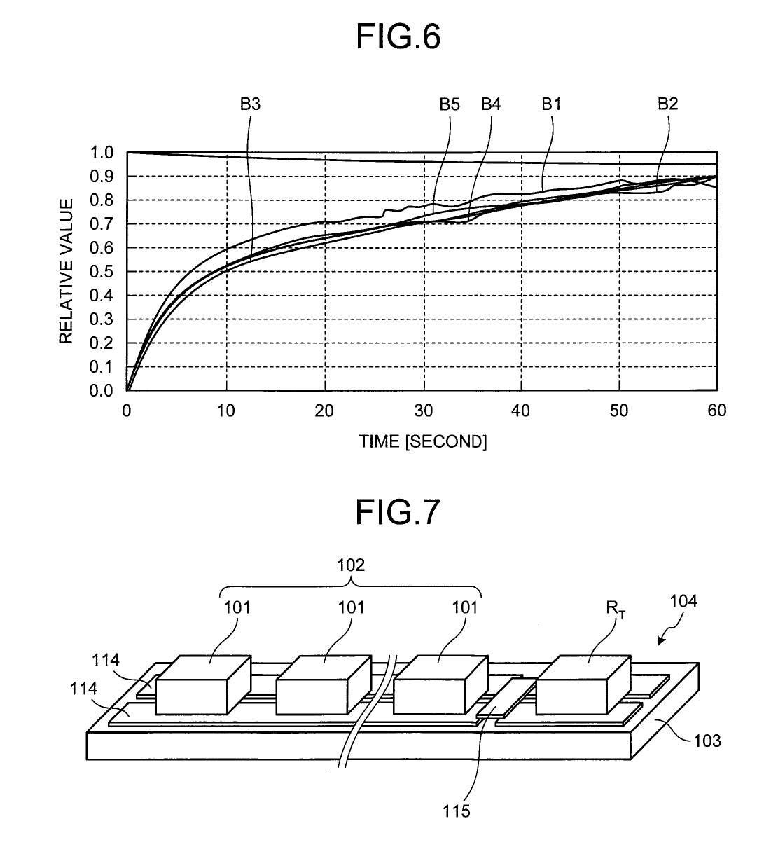

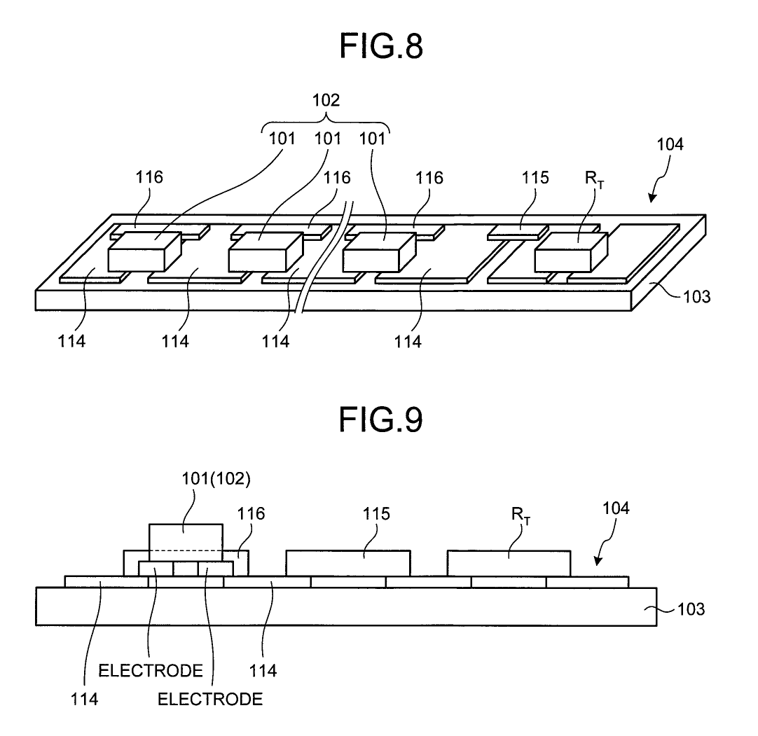

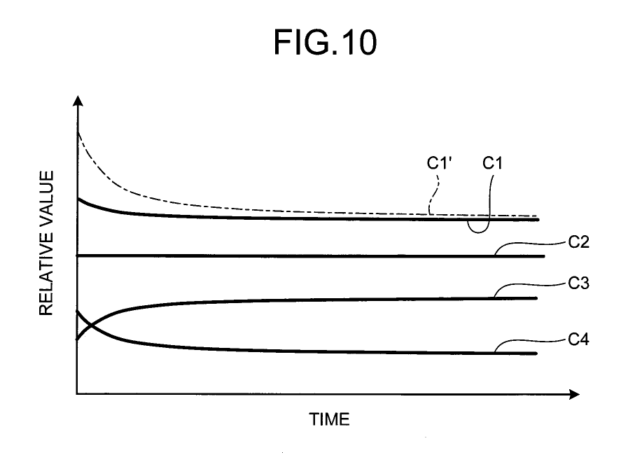

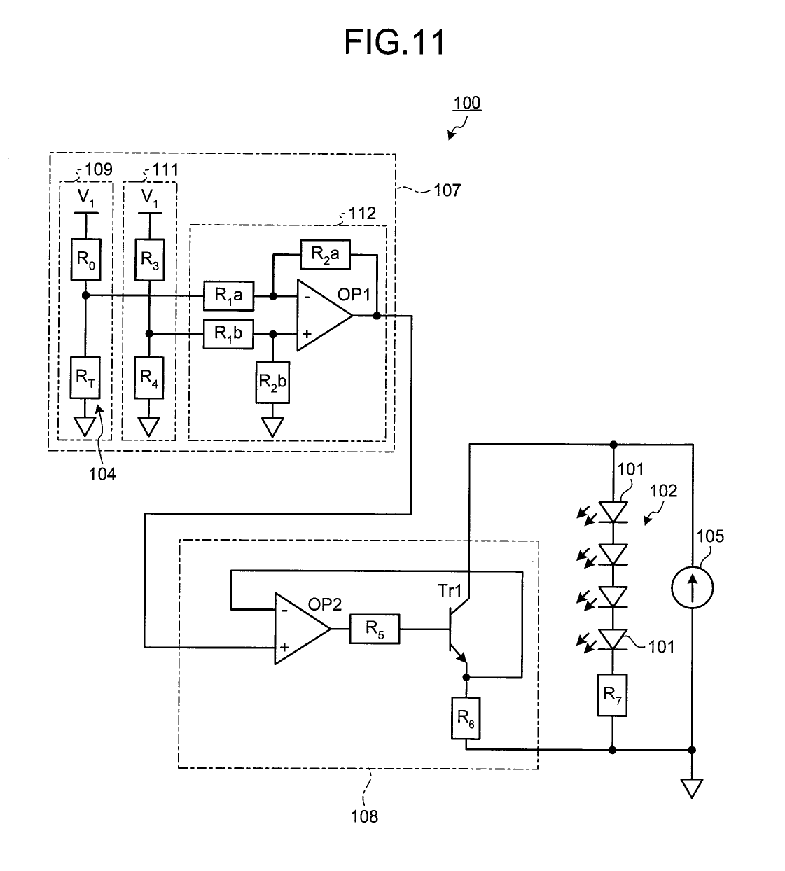

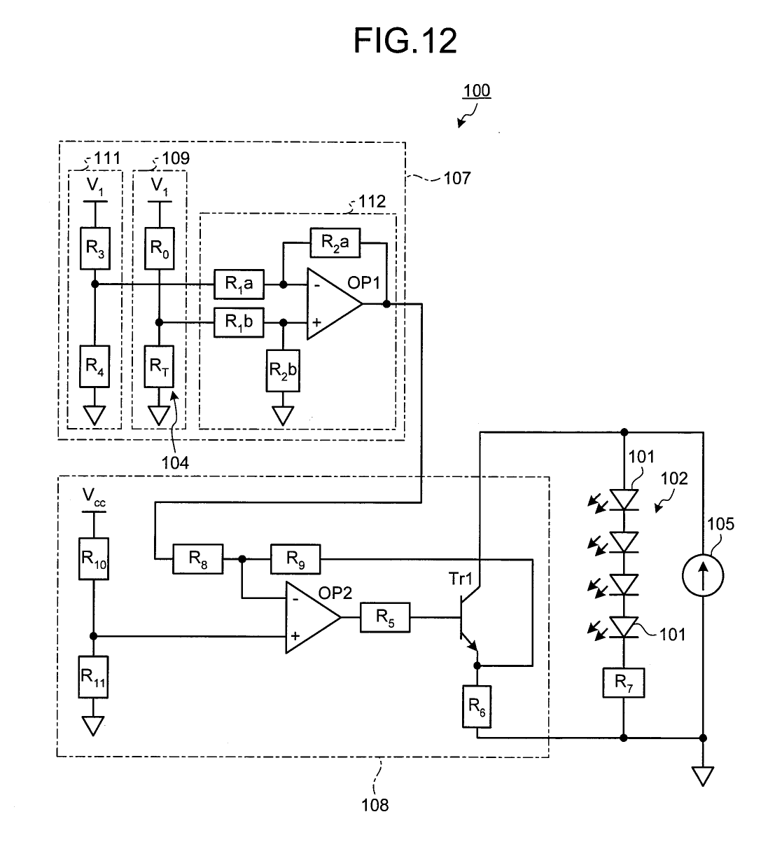

FIG. 1 is a schematic diagram of a configuration of an illuminating device according to an embodiment of the present invention. FIG. 2 is a schematic perspective view of an image reading apparatus to which the illuminating device according to the embodiment of the present invention has been applied. FIG. 3 is a schematic diagram of a configuration of the image reading apparatus to which the illuminating device according to the embodiment of the present invention has been applied. FIG. 4 is a diagram for explaining a relationship between an LED-device temperature and an LED-device light quantity when a current and a voltage supplied to an LED device of the illuminating device according to the embodiment of the present invention are made constant. FIG. 5 is a diagram for explaining a relationship between an LED-device light-quantity attenuation rate and an LED-device temperature change rate when the current and the voltage supplied to the LED device of the illuminating device according to the embodiment of the present invention are made constant. FIG. 6 is a diagram for explaining the LED-device temperature change rate at each predetermined drive current when the voltage supplied to the LED device of the illuminating device according to the embodiment of the present invention is made constant. FIG. 7 is a schematic perspective view of an example of a substrate (with the LED devices in parallel connection) of the illuminating device according to the embodiment of the present invention. FIG. 8 is a schematic perspective view of an example of the substrate (with the LED devices in series connection) of the illuminating device according to the embodiment of the present invention. FIG. 9 is a schematic cross-sectional view of an example of the substrate (with the LED devices in parallel connection) of the illuminating device according to the embodiment of the present invention. FIG. 10 is a diagram for explaining variation in luminance of the LED device of the illuminating device according to the embodiment of the present invention. FIG. 11 is a diagram of a specific example of a configuration of an analog circuit of the illuminating device according to the embodiment of the present invention. FIG. 12 is a diagram of another specific example of the configuration of the analog circuit of the illuminating device according to the embodiment of the present invention.

As illustrated in FIGS. 2 and 3, an illuminating device 100 according to the embodiment of the present invention illuminates an original S, which is a target to be illuminated. Herein, the illuminating device 100 is explained as being applied to an image reading apparatus 1. In the following embodiments, the image reading apparatus 1 is described as an image scanner; however, the present invention is not limited to this example, and the image reading apparatus 1 may be any device that scans an image reading medium with an image sensor, such as a copier, a facsimile machine, or a character recognizing apparatus.

The image reading apparatus 1 reads an image on the original S, which is an image-read object that is illuminated by the illuminating device 100. The image reading apparatus 1 optically scans the image on the original S and converts the scanned image to electrical signals to read the image as image data, and includes the illuminating device 100, a lens 2 which is an imaging optical system, and a line sensor 3. The image reading apparatus 1 of the present embodiment further includes a glass plate 4, a platen 5, and a conveying device 6. In the image reading apparatus 1 of the present embodiment, the platen 5 on which the original S is to be placed, the glass plate 4, the illuminating device 100, the lens 2, and the line sensor 3 are arranged in this order from the platen 5 side with respect to a direction of an optical axis of the lens 2.

The illuminating device 100 includes at least one LED device 101. In the present embodiment, the illuminating device 100 includes a plurality of the LED devices 101. The illuminating device 100 is configured such that the LED devices 101 are arrayed along a main-scanning direction. The LED devices 101 arrayed along the main-scanning direction constitute an LED-array light source 102 that functions as a linear light source. In the illuminating device 100, the LED-array light source 102 irradiates the original S with light.

Each of the LED devices 101 is mounted on a mounting surface of a substrate 103, such as a printed circuit board (see, for example, FIGS. 1 and 7). Each of the LED devices 101 is set such that a light emitting surface thereof faces the original S, that is, the glass plate 4 to be described later, and a light emission direction thereof is toward the original S (toward the glass plate 4).

In the illuminating device 100, the LED devices 101 are arranged in a line at regular intervals in a predetermined array direction, that is, in the main scanning direction, to form the LED-array light source 102. In other words, the LED-array light source 102, which functions as the linear light source, includes the plurality of LED devices 101 arrayed along the main-scanning direction of the line sensor 3, so that the LED-array light source 102 is able to irradiate the original S with linear light along the main-scanning direction.

The illuminating device 100 may also include a white reflecting surface that is arranged on a plane parallel to an optical axis of each of the LED devices 101 that form the LED-array light source 102 and that reflects light emitted from the LED-array light source 102 toward the original S, and a plate-like mirror surface that reflects light emitted from the LED-array light source 102 or that reflects the reflected light from the white reflecting surface toward the original S. In this case, the illuminating device 100 may have the LED-array light source 102 and the white reflecting surface on one side of a plane that contains both the optical axis of the lens 2 and a pixel array of the line sensor 3 with respect to a sub-scanning direction perpendicular to the main-scanning direction and the mirror surface on the other side of that plane. Because the illuminating device 100 includes the white reflecting surface and the mirror surface, it is possible to stabilize illumination distribution along the sub-scanning direction, for example.

The glass plate 4 is made of a rectangular plate-like transparent material, for example, glass in the present embodiment, and is placed between the LED-array light source 102 and the original S with respect to the direction of the optical axis of the LED-array light source 102. The glass plate 4 presses the original S toward the platen 5 to prevent the original S from floating from the platen 5.

The lens 2 focuses the reflected light from the original S to form an image. Specifically, the lens 2 focuses the reflected light that has been emitted from the illuminating device 100 and reflected at the original S to a light receiving surface of the line sensor 3 to form an image.

In the line sensor 3, a plurality of pixels receive reflected light that has been emitted from the illuminating device 100, reflected at the original S, and focused through the lens 2, and the reflected light is converted to electrical signals to read an image. The line sensor 3 is, for example, a linear image sensor (one-dimensional image sensor) in which a plurality of photoelectric conversion elements (imaging elements) that receive light and generate electric charges are linearly arranged as the plurality of pixels. In the line sensor 3, an array direction of the photoelectric conversion elements corresponds to the main-scanning direction of the line sensor 3, and a direction perpendicular to the main-scanning direction corresponds to the sub-scanning direction. In FIG. 3, a depth direction in the figure corresponds to the main-scanning direction of the line sensor 3, and a left-right direction in the figure corresponds to the sub-scanning direction of the line sensor 3.

The conveying device 6 is a relative movement mechanism that causes a relative movement between the line sensor 3 and the original S. More specifically, the conveying device 6 conveys the original S to a position where the original S faces the line sensor 3, that is, a position where imaging is possible. The conveying device 6 includes two conveying rollers 61 and 62 that are located opposite to each other and are rotatably supported, a conveying motor 63 serving as rotation driving means for rotating the conveying roller 61, and a motor control circuit (not illustrated) that controls driving of the conveying motor 63. In the conveying device 6, the conveying roller 61 rotates when the conveying motor 63 is controlled to be rotated by the motor control circuit. The original S enters between the conveying roller 61, one of the rollers, and the conveying roller 62, the other one of the rollers, along with the rotation of the conveying roller 61, and is conveyed in a conveying direction (a direction along the sub-scanning direction). Therefore, in the image reading apparatus 1, the conveying device 6 causes the relative movement between the line sensor 3 and the original S in the sub-scanning direction to thereby allow the line sensor 3 to scan the original S in the sub-scanning direction and read a two-dimensional image on the original S.

In the image reading apparatus 1 configured as described above, light that has been emitted from the illuminating device 100 toward the original S is reflected at the original S and then converged by the lens 2 to form an image, and the reflected light through the lens 2 enters the line sensor 3 and is converted into an electrical signal, so that an image on the original S is read per read line along the main-scanning direction. In the image reading apparatus 1, it is possible to read two-dimensional image data from the original S as the conveying device 6 causes the relative movement between the line sensor 3 and the original S in the sub-scanning direction to thereby allow the line sensor 3 to sequentially read the image along the sub-scanning direction.

While it has been explained that the conveying device 6, the relative movement mechanism of the image reading apparatus 1, moves the original S along the sub-scanning direction to cause the relative movement between the line sensor 3 and the original S in the sub-scanning direction, it is possible to move the line sensor 3 together with the illuminating device 100 along the sub-scanning direction to cause the relative movement between the line sensor 3 and the original S in the sub-scanning direction. In other words, although it has been explained that the image reading apparatus 1 of the present embodiment is an automatic-document-feed type scanner that moves the original S with respect to the line sensor 3 to cause the relative movement between the line sensor 3 and the original S in the sub-scanning direction, the image reading apparatus 1 may be a flat head scanner or a handy scanner that moves the line sensor 3 with respect to the original S to cause the relative movement between the line sensor 3 and the original S in the sub-scanning direction.

Meanwhile, luminous efficiency of the LED devices 101 employed in the illuminating device 100 as mentioned above changes as temperature of the LED devices 101, for example, pn-junction temperature (so-called junction temperature), changes. In general, the luminous efficiency of the LED devices 101 tends to decrease as electrical energy not converted into light in the LED devices 101 is converted into heat and the temperature of the LED devices 101 increases. For example, in some cases, a few percents to ten plus a few percents of light quantity of the LED devices 101 may be lost in a few minutes after the LED devices 101 are turned on. Such change in the light quantity of the light source may degrade quality of image density in the image reading apparatus 1 for example.

To suppress such variation in light quantity, as illustrated in FIG. 1, in the illuminating device 100 and the image reading apparatus 1 of the present embodiment, a drive current supplied to the LED devices 101 is linearly changed according to change in temperature of the LED devices 101 detected by a thermistor 104 provided as means for detecting temperature.

In FIG. 1, the illuminating device 100 is illustrated as having the plurality of LED devices 101 connected in parallel to constitute the LED-array light source 102; however, the configuration is not limited to this illustration. The plurality of LED devices 101 may be connected in series. The illuminating device 100 illustrated in FIG. 1 includes the plurality of LED devices 101 as described above, a constant current source 105 serving as a constant current drive circuit, and a plurality of limited current resistors 106.

The constant current source 105 may constitute various types of commonly-known constant current drive circuits, and supplies drive electric power at a constant current value. The constant current source 105 generates and outputs a current of constant magnitude independent of change in the surrounding temperature and change in voltage.

Each LED device 101 is connected to the constant current source 105. Each LED device 101 emits light of a predetermined amount of luminescence according to the drive current supplied from the constant current source 105. In each LED device 101, an output, that is, the amount of luminescence, relatively increases as the drive current supplied from the constant current source 105 relatively increases, and the output, that is, the amount of luminescence, relatively decreases as the drive current relatively decreases. The plurality of LED devices 101 of the present embodiment are connected in parallel with each other and are connected to the same constant current source 105.

Each limited current resistor 106 is connected between a corresponding one of the LED devices 101 and the constant current source 105, and adjusts the drive current supplied from the constant current source 105 to the corresponding one of the LED devices 101 and the amount of luminescence which is the output of the corresponding one of the LED devices 101. In the present embodiment, each limited current resistor 106 and the corresponding one of the LED devices 101 are connected in series.

Namely, in the illuminating device 100, the plurality of LED devices 101 connected in parallel with each other are respectively connected in series with the limited current resistors 106 so that the drive current supplied to each LED device 101 is adjusted to adjust the amount of luminescence, which is the output of each LED device 101.

FIG. 4 is a diagram for explaining a relationship between an LED-device temperature and an LED-device light quantity when a current and a voltage supplied to the LED devices 101 of the illuminating device 100 are made constant, where a vertical axis represents a relative value and a horizontal axis represents a time period elapsed from a time point at which the LED devices are turned on. In FIG. 4, a solid line represents a relative value of the LED-device light quantity (relative light quantity) verses the elapsed time period, and a dotted line represents a relative value of the LED-device temperature (relative temperature) verses the elapsed time period. FIGS. 5 and 6 are graphs of measured change in light quantity and measured temperature of the LED devices 101 when the plurality of LED devices 101 are connected in parallel as described above. FIG. 5 is a diagram for explaining a relationship between an LED-device light-quantity attenuation rate and an LED-device temperature change rate when the current and the voltage supplied to the LED devices 101 of the illuminating device 100 are made constant, where a vertical axis represents a relative value and a horizontal axis represents a time period elapsed from a time point at which the LED devices are turned on. In FIG. 5, a line A1 represents a relative value of the LED-device light quantity (relative light quantity) versus the elapsed time period, a line A2 represents a relative value of the LED-device light-quantity attenuation rate (relative light-quantity attenuation rate) versus the elapsed time period, and a line A3 represents a relative value of the LED-device temperature change rate (relative temperature change rate) versus the elapsed time period. FIG. 6 is a diagram for explaining the LED-device temperature change rate at each predetermined drive current when the voltage supplied to the LED devices 101 of the illuminating device 100 is made constant, where a vertical axis represents a relative value and a horizontal axis represents a time period elapsed from a time point at which the LED devices are turned on. In FIG. 6, a line B1 represents a relative value of the LED-device temperature change rate versus the elapsed time period when the drive current supplied to the LED devices 101 is set to 0.3 A, a line B2 represents a relative value of the LED-device temperature change rate versus the elapsed time period when the drive current supplied to the LED devices 101 is set to 0.4 A, a line B3 represents a relative value of the LED-device temperature change rate versus the elapsed time period when the drive current supplied to the LED devices 101 is set to 0.5 A, a line B4 represents a relative value of the LED-device temperature change rate versus the elapsed time period when the drive current supplied to the LED devices 101 is set to 0.6 A, and a line B5 represents a relative value of the LED-device temperature change rate versus the elapsed time period when the drive current supplied to the LED devices 101 is set to 0.7 A.

As described above, in the illuminating device 100, when the electrical energy that has not been converted into light is converted into heat in the LED devices 101 and the temperature of the LED devices 101 increases accordingly, the luminous efficiency of the LED devices 101 tends to decrease. Meanwhile, as illustrated in FIG. 4, a transient response relationship between the LED-device temperature and the LED-device light quantity of the LED devices 101 tends to be of a first-order lag response relationship. Furthermore, as illustrated in FIG. 5, a time constant of the change in light quantity (the relative light-quantity attenuation rate) of the LED devices 101 and a time constant of the change in temperature (the relative temperature change rate) of the LED devices 101 tend to become extremely close to each other. Moreover, as illustrated in FIG. 6, the time constants of the changes in temperature (the relative temperature change rates) of the LED devices 101 may be considered to be substantially the same regardless of the drive current heating values) supplied to the LED devices 101.

Consequently, utilizing the above-mentioned characteristics, in the illuminating device 100, because the change in temperature of the LED devices 101, which is a detected amount, is detected by the thermistor 104, and the drive current supplied to the LED devices 101 is linearly changed according to the change in temperature of the LED devices 101, it is possible to stabilize the light quantity of the LED devices 101 against the change in temperature of the LED devices 101, in particular, against the change in output characteristics due to the change in temperature of the LED devices 101. Therefore, it is possible to easily suppress the change in light quantity due to the change in temperature, for example, initially after the LED devices 101 are turned on.

If, for example, change in temperature of the LED devices is directly controlled by cooling the LED devices by cooling means such as a fan to control the change in light quantity, then control circuits for the temperature detecting unit and for a microcomputer for performing the cooling control become complex, and it is also likely that wind generated by the fan passes through an image reading unit such as the line sensor 3, resulting in decreased dust-proof performance. In contrast, in the illuminating device 100 of the present embodiment, it is possible to easily suppress the change in light quantity of the LED devices 101 in the above-described manner without degrading the dust-proof performance.

Furthermore, if, for example, the amount of luminescence of the LED devices are detected by an illuminance sensor or the like and then duty control is performed by PWM control or the like for lighting the LED devices, the illuminance sensor directly detects and controls the amount of luminescence of the LED devices. Therefore, if the illuminating device 100 is applied to the image reading apparatus 1 in which a distance between the original S and the LED-array light source 102 are relatively short, reflected light from the original may disturb the illuminance sensor that detects the amount of luminescence of the LED devices. In this case, it is necessary to perform detection of the amount of luminescence of the LED devices by the illuminance sensor and adjustment of the light quantity according to the change in temperature of the LED devices while the original S is not on the platen 5, or it is necessary to lengthen the LED-array light source 102 up to an area unaffected by the reflected light from the original S. In contrast, in the illuminating device 100 of the present embodiment, the change in temperature of the LED devices 101 is detected as the detected amount by the thermistor 104, and the drive current supplied to the LED devices 101 is linearly changed according to the change in temperature of the LED devices 101, and thus it is possible to stabilize the light quantity of the LED devices 101 against the change in temperature. Therefore, the light quantity of the LED devices 101 is not used as the detection amount, that is, an amount of control, for adjusting the light quantity, so that it is possible to easily suppress the change in light quantity of the LED devices 101 without being affected by disturbance like the reflected light from the original upon adjustment of the light quantity of the LED devices 101. Further, when, for example, the light quantity is adjusted during reading of the original, it is possible to infallibly suppress the change in light quantity of the LED devices 101 without being affected by variation in the reflected light due to density differences in the original.

Furthermore, if, for example, in the illuminating device 100 of the present embodiment, a lifetime of each LED device 101 is to be checked after the LED devices 101 have been turned on and the change in light quantity has stabilized to some extent during initial operation of the apparatus, it is possible to suppress the change in light quantity in a short period of time against the change in temperature after lighting each LED device 101. Accordingly, it is possible to suppress the change in light quantity by linearly changing the drive current according to the change in temperature of the LED devices 101 even when the temperature of the LED devices 101 has not stabilized. Therefore, the light quantity of each LED device 101 is stabilized soon after the lighting, and thus it is possible to shorten a wait time period for stabilization of the light quantity before a lifetime check. As a result, it is possible to promptly shift to a normal operation after activation.

As described above, the thermistor 104 detects the change in temperature of the LED devices 101. In the present embodiment, the thermistor 104 is preferably configured to detect the detected amount of change in temperature of the LED devices 101 according to a resistance value, and to include a resistor R_{T} (see FIG. 1) having the resistance value that linearly changes according to the change in temperature of the LED devices 101. In the present embodiment, the thermistor 104, which is the means for detecting the temperature, is a so-called linear PTC thermistor that has a positive temperature coefficient and includes the resistor R_{T} having the resistance value that changes substantially linearly according to the change in temperature. The resistor R_{T} of the thermistor 104 is configured such that the resistance value increases when the temperature of the LED devices 101 increases and the resistance value decreases when the temperature of the LED devices 101 decreases. The resistor R_{T} of the thermistor 104 is arranged near the LED-array light source 102, and detects the change in the temperature of the LED devices 101.

In this configuration, the illuminating device 100 includes the thermistor 104 that detects the detected amount of change in temperature of the LED devices 101 according to the resistance value and that includes the resistor R_{T} having the resistance value that linearly changes according to the change in temperature of the LED devices 101. Therefore, a configuration for linearly changing the drive current supplied to the LED devices 101 with respect to the change in temperature of the LED devices 101 may be realized by an analog circuit. Consequently, a so-called microcomputer, an analog-to-digital converter (ADC) that converts an analog signal to a digital signal, a digital-to-analog converter (DAC) that converts a digital signal to an analog signal, and the like are not needed. As a result, it is possible to suppress the change in light quantity inexpensively.

A structural unit, in the illuminating device 100 of the present embodiment, which changes the drive current supplied to the LED devices 101 linearly according to the change in temperature of the LED devices 101, includes, for example as illustrated in FIG. 1, the thermistor 104 as described above, the constant current source 105 as described above, a voltage conversion amplifier circuit 107 serving as means for converting and amplifying voltage, and an electronic load circuit 108 serving as means for supplying electronic load.

The voltage conversion amplifier circuit 107 converts the detected amount that is obtained by the thermistor 104 to a detected voltage, and amplifies the detected voltage. The change in temperature of the LED devices 101 is detected as the change in resistance value of the resistor R_{T} of the thermistor 104, and the voltage conversion amplifier circuit 107 converts the resistance value of the resistor R_{T} that is the detected amount to the detected voltage corresponding to a resistor divided voltage of the resistor R_{T}. Namely, the detected voltage changes with the change in resistor divided voltage of the resistor R_{T} that occurs due to the change in resistance of the resistor R_{T} of the thermistor 104 in accordance with the change in temperature of the LED devices 101. In the present embodiment, because a change rate of the resistance value of the thermistor 104 with respect to the change in temperature is relatively small, the voltage conversion amplifier circuit 107 amplifies the detected voltage and then inputs the amplified detected voltage to the electronic load circuit 108.

The electronic load circuit 108 is connected to each of the LED devices 101 in parallel with respect to the constant current source 105, and divides a current from the constant current source 105 according to a load. More specifically, the electronic load circuit 108 increases or decreases a current that flows through the load according to the voltage amplified by the voltage conversion amplifier circuit 107. When the temperature of the LED devices 101 increases, the electronic load circuit 108 decreases the current that flows through the load according to the voltage that is converted and amplified by the voltage conversion amplifier circuit 107, and, when the temperature of the LED devices 101 decreases, the electronic load circuit 108 increases the current that flows through the load according to the voltage that is converted and amplified by the voltage conversion amplifier circuit 107.

In the illuminating device 100, when, for example, the temperature of the LED devices 101 increases, the resistance value of the resistor R_{T} of the thermistor 104 linearly increases with the increase in temperature of the LED devices 101, and the resistor divided voltage of the resistor R_{T}, which is converted by the voltage conversion amplifier circuit 107, that is, the detected voltage, also linearly increases with the increase in temperature of the LED devices 101. Further, the detected voltage amplified by the voltage conversion amplifier circuit 107 is inverted and amplified by either the voltage conversion amplifier circuit 107 or the electronic load circuit 108, so that the voltage that affects the load of the electronic load circuit 108 linearly decreases with the increase in temperature of the LED devices 101. When the temperature of the LED devices 101 decreases, an opposite result is obtained, that is, the voltage that affects the load of the electronic load circuit 108 linearly increases with the decrease in temperature of the LED devices 101.

In this manner, in the illuminating device 100, when the temperature of the LED devices 101 increases, the voltage that affects the load of the electronic load circuit 108 decreases, so that the current that flows through the load linearly decreases with the increase in the temperature of the LED devices 101 and accordingly the drive current supplied to the LED devices 101 linearly increases. On the other hand, in the illuminating device 100, when the temperature of the LED devices 101 decreases, the voltage that affects the load of the electronic load circuit 108 increases, so that the current that flows through the load linearly increases with the decrease in the temperature of the LED devices 101 and accordingly the drive current supplied to the LED devices 101 linearly decreases. As a result, in the illuminating device 100, it is possible to stabilize the light quantity of the LED devices 101 against the change in temperature of the LED devices 101, in particular, against the change in output characteristics due to the change in temperature of the LED devices 101. Thus, it is possible to easily suppress the change in light quantity due to the change in temperature, for example, initially after the LED devices 101 are turned on.

The voltage conversion amplifier circuit 107 preferably includes a temperature-voltage conversion circuit 109 serving as temperature-voltage converting means, a constant voltage source 110, an offset-voltage regulator circuit 111 serving as means for regulating offset-voltage, and a differential amplifier 112 serving as amplifying means.

The temperature-voltage conversion circuit 109 converts the detected amount that is obtained by the thermistor 104 to the detected voltage, in particular, converts the detected amount that is obtained by the thermistor 104 to the detected voltage according to the resistance value of the resistor R_{T} of the thermistor 104, which linearly changes according to the change in temperature of the LED devices 101. The constant voltage source 110 outputs a voltage as a reference voltage to the temperature-voltage conversion circuit 109. The offset-voltage regulator circuit 111 adjusts an offset voltage to be lower than the detected voltage that is obtained by the temperature-voltage conversion circuit 109, at the minimum operating temperature (for example, 10° C.) of the LED devices 101. The differential amplifier 112 amplifies the detected voltage based on a difference voltage between the detected voltage obtained by the temperature-voltage conversion circuit 109 and the offset voltage obtained by the offset-voltage regulator circuit 111. If the voltage conversion amplifier circuit 107 is configured to invert and amplify the detected voltage, a differential inverting amplifier is used as the differential amplifier 112 for example, to receive the detected voltage from the temperature-voltage conversion circuit 109 and the offset voltage from the offset-voltage regulator circuit 111, to invert and amplify the detected voltage based on the difference voltage between the received voltages, and to output the inverted and amplified detected voltage. The voltage inverted and amplified by the differential amplifier 112 is input to the electronic load circuit 108.

In this case, the voltage conversion amplifier circuit 107 is able to cancel an extra offset voltage of an output voltage received from the differential amplifier 112, and thus to increase the degree of amplification. Furthermore, as described above, the current that flows through the load of the electronic load circuit 108 linearly changes according to the output voltage that is obtained by the differential amplifier 112, and, if the offset voltage is the output voltage obtained by the differential amplifier 112 and the offset voltage acts on the load of the electronic load circuit 108, the current that flows through the load of the electronic load circuit 108 is at a minimum value. If the temperature of the LED devices 101 is saturated, that is, if the increase in temperature of the LED devices 101 is stabilized and therefore the resistance value of the resistor R_{T} of the thermistor 104, which linearly changes according to the change in temperature of the LED devices 101, is stabilized, it is preferable that the offset voltage is 0 (zero). Therefore, if the offset voltage output from the differential amplifier 112 is 0 after the temperature of the LED devices 101 has increased upon lighting the LED devices 101 and the increase in temperature has stabilized, the current that flows through the load of the electronic load circuit 108 becomes substantially 0 (zero). Consequently, the drive current supplied to the LED devices 101 becomes constant, and the LED devices 101 are able to emit light stably.

In the voltage conversion amplifier circuit 107, the offset-voltage regulator circuit 111 preferably shares the constant voltage source 110 and a voltage control unit 113 serving as a voltage control means preferably controls a voltage of the constant voltage source 110. In this configuration, the illuminating device 100 is able to appropriately adjust the offset voltage and the degree of amplification of the differential amplifier 112 depending on a situation by causing the voltage control unit 113 to adjust the voltage of the constant voltage source 110. Therefore, the voltage conversion amplifier circuit 107 functions as a temperature compensation circuit for luminance of the LED devices 101 for example, and it becomes possible to reduce the variation in luminance due to the surrounding temperature, atmosphere around the light source, and the like.

If the illuminating device 100 includes a plurality of the LED devices 101 as described in the present embodiment, for example as illustrated in FIG. 7, the illuminating device 100 is preferably configured such that the substrate 103 on which the plurality of LED devices 101 are mounted in an array and to which respective electrodes of the LED devices 101 are connected via heat conductive members 114 heat-conductibly is provided, and the thermistor 104 is mounted on the substrate 103 so as to detect the change in temperature of the LED devices 101 via the heat conductive members 114 and an insulated heat conductive member 115 that is connected to the heat conductive members 114 heat-conductibly and that is electrically-insulated. Here, the heat conductive members 114 may be, for example, a solid pattern uniformly covered with copper foil, and, the insulated heat conductive member 115 may be, for example, an inexpensive ceramic resistor having a resistance value of a few MΩ. In this configuration, it is possible to connect anodes and cathodes of the plurality of LED devices 101 connected in parallel with each other, each with a single heat conductive member 114. Therefore, it is possible to reduce thermal resistance by increasing an area of the heat conductive member 114, so that it becomes possible to equalize the temperatures of the LED devices 101. In other words, it is possible to equalize the changes in temperatures of the plurality of LED device 101 constituting the LED-array light source 102. Furthermore, because the thermistor 104 is connected to the heat conductive members 114 via the insulated heat conductive member 115, it is possible to substantially equalize temperatures of the heat conductive members 114, the resistor R_{T}, and the plurality of LED devices 101 (electrode portions) while electrically insulating the thermistor 104 from the plurality of LED devices 101. As a result, it is possible to detect the change in temperature of each LED device 101 that forms the LED-array light source 102 by using the single resistor R_{T} without providing resistors R_{T} individually for all the LED devices 101.

In the illuminating device 100, when the plurality of LED devices 101 constituting the LED-array light source 102 are connected in series, a transfer path of heat generated by the LED devices 101 goes through the LED devices 101 via the electrodes of the LED devices 101. In general, thermal resistance of the LED devices 101 is relatively high, and thus the plurality of LED devices 101 that are connected in series has a temperature distribution where a temperature at the center of the array of the LED-array light source 102 is high and temperatures at the ends of the array of the LED-array light source 102 are low. In other words, when the plurality of LED devices 101 that form the LED-array light source 102 are connected in series, it is likely that a difference in light quantity is generated between the LED device 101 at the center of the array of the LED-array light source 102 and the LED devices 101 at the ends of the array of the LED-array light source 102. Accordingly, as illustrated in FIGS. 8 and 9 for example, when the plurality of LED devices 101 that form the LED-array light source 102 are connected in series, the illuminating device 100 is preferably configured such that the heat conductive members 114, each connecting the electrodes of the LED devices 101 to one another in a heat conducting manner, are further connected to one another via insulated heat conductive members 116 that are electrically insulated. Here, the insulated heat conductive members 116 may be, for example, cheap ceramic resistors having a resistance value of a few MΩ, similarly to the insulated heat conductive member 115.

In this configuration, the heat conductive members 114, each connecting an anode of one of the LED devices 101 that are connected in series with each other to a cathode of an adjacent one of the LED devices 101, are connected to one another by the insulated heat conductive members 116 in a heat conducting manner and in a mutually-insulated manner. Therefore, in the LED devices 101 connected in series, the entire thermal resistance in areas connected with the heat conductive members 114 and the insulated heat conductive members 116 is decreased, and thus it is possible to equalize the temperatures of the LED devices 101. Namely, it is possible to equalize the changes in temperatures of the LED devices 101 constituting the LED-array light source 102. Furthermore, by connecting the thermistor 104 to one of the heat conductive members 114, in the present embodiment to the heat conductive member 114 at the end, via the insulated heat conductive member 115, it is possible to substantially equalize the temperatures of the heat conductive members 114, the resistor R_{T}, and the LED devices 101 (the electrode portions) while electrically insulating the thermistor 104 from each of the LED devices 101. As a result, it is possible to detect the change in temperature of each LED device 101 that forms the LED-array light source 102 with the single resistor R_{T} without providing resistors R_{T} individually for all the LED devices 101.

FIG. 10 is a diagram for explaining variation in luminance of the LED devices of the illuminating device according to the embodiment of the present invention, where a vertical axis represents a relative value and a horizontal axis represents a time period elapsed from a time point at which the LED devices are turned on. In FIG. 10, a line C1 represents a relative value of the luminance of the LED devices 101 of the illuminating device 100 of the present embodiment, a line C2 represents a relative value (constant) of a current supplied from the constant current source 105 of the illuminating device 100 of the present embodiment, a line C3 represents a relative value of the drive current supplied to each of the LED devices 101 of the illuminating device 100 of the present embodiment, a line C4 represents a relative value of a current supplied to the load of the electronic load circuit 108 of the illuminating device 100 of the present embodiment, and a line C1′ represents a relative value of luminance of LED devices according to a comparative example. In the illuminating device of the comparative example, a drive current supplied to each of the LED devices is set to a constant value after the LED devices are turned on. In contrast, in the illuminating device 100 of the present embodiment, after the LED devices 101 are turned on and along with the increase in temperature of the LED devices 101, the current that flows through the load of the electronic load circuit 108 linearly changes (the line C4) and the drive current supplied to each of the LED devices 101 linearly increases (the line C3) with the increase in temperature of the LED devices 101. Consequently, it is possible to stabilize the light quantity of the LED devices 101 against the change in the output characteristics due to the change in temperature of the LED devices 101. As a result, it is possible to suppress the change in light quantity due to the change in temperature of the LED devices 101 initially upon lighting.

With reference to FIG. 11, a specific example of a configuration of an analog circuit of the illuminating device 100 is described below. While a configuration in which the LED devices 101 that form the LED-array light source 102 are connected in series is illustrated in the figure, a connection is not limited thereto. For example, a parallel connection is also applicable. In addition, explanation given below is based on an assumption that the detected voltage converted by the voltage conversion amplifier circuit 107 is further inverted and amplified by the voltage conversion amplifier circuit 107.

The analog circuit of the illuminating device 100 illustrated in FIG. 11 includes the LED devices 101, the thermistor 104, the constant current source 105, op-amps (operational amplifiers) OP1 and OP2, a transistor Tr1 (or a field-effect transistor (FET)), and a plurality of resistors R.

In this configuration, the voltage conversion amplifier circuit 107, which is described above, includes the op-amp (operational amplifier) OP1, an electric-power input terminal for receiving a reference voltage V1 from the constant voltage source 110 (see FIG. 1), the resistor R_{T} of the thermistor 104, and the resistors R₀, R₁a, R₁b, R₂a, R₂b, R₃, and R₄. The electric-power input terminal for receiving the reference voltage V1 from the constant voltage source 110, the resistor R₀, and the resistor R_{T} form the temperature-voltage conversion circuit 109, which is described above. The electric-power input terminal for receiving the reference voltage V1 from the constant voltage source 110, and the resistors R₃ and R₄ form the offset-voltage regulator circuit 111, which is described above. The op-amp OP1, the resistors R₁a, R₁b, R₂a, and R₂b form the differential amplifier 112, which is described above, in particular, in this example the differential inverting amplifier. The electronic load circuit 108, which is described above, includes the op-amp OP2, the transistor Tr1, and the resistors R₅ and R₆.

The LED devices 101 are connected in series with respect to the constant current source 105. An anode of a predetermined one of the LED devices 101 is connected to an output terminal of the constant current source 105 and a cathode of a predetermined one of the LED devices 101 is connected to an input terminal of the constant current source 105 via the resistor R₇.

An inverting input terminal (−) of the op-amp OP1 is connected to the electric-power input terminal for receiving the reference voltage V1 from the constant voltage source 110 (see FIG. 1), via the resistors R₁a and R₀, and is also connected to one end of the resistor R_{T} of the thermistor 104. The other end of the resistor R_{T} is grounded.

A non-inverting input terminal (+) of the op-amp OP1 is connected to one end of the resistor R₂b that is set to have a resistance value equal to that of the resistor R₂a, which will be described later. The other end of the resistor R₂b is grounded. Furthermore, the non-inverting input terminal (+) of the op-amp OP1 is connected to an electric-power input terminal for receiving the reference voltage V1 from the constant voltage source 110 (see FIG. 1), via the resistor R₁b that is set to have a resistance value equal to that of the resistor R₁a, and the resistor R₃, and is also connected to one end of the resistor R₄ via the resistor R₁b. The other end of the resistor R₄ is grounded.

An output terminal of the op-amp OP1 is connected to the inverting input terminal (−) of the op-amp OP1 via the resistor R₂a, and is also connected to a non-inverting input terminal (+) of the op-amp OP2.

The non-inverting input terminal (+) of the op-amp OP2 is connected to the output terminal of the op-amp OP1 as described above. An inverting input terminal (−) of the op-amp OP2 is connected to an emitter of the transistor Tr1. An output terminal of the op-amp OP2 is connected to a base of the transistor Tr1 via the resistor R₅.

A collector of the transistor Tr1 is connected to the output terminal of the constant current source 105. The emitter of the transistor Tr1 is connected to the input terminal of the constant current source 105 via the resistor R₆, and is also connected to the inverting input terminal (−) of the op-amp OP2 as described above. The base of the transistor Tr1 is connected the output terminal of the op-amp OP2 via the resistor R₅ as described above.

In the analog circuit of the illuminating device 100 having the configuration as described above with reference to FIG. 11, when, for example, the temperature of the LED devices 101 increases, the resistance value of the resistor R_{T} linearly increases with the increase in the temperature of the LED devices 101, so that the resistor divided voltage of the resistor R_{T} that divides the reference voltage V1 received from the constant voltage source 110, that is, the detected voltage, linearly increases with the increase in temperature of the LED devices 101. The detected voltage is input to the op-amp OP1, then inverted and amplified by the op-amp OP1, then output to the op-amp OP2, and then amplified by the op-amp OP2, so that the voltage that affects the base of the transistor Tr1 linearly decreases with the increase in temperature of the LED devices 101. Accordingly, the current that flows through the load of the electronic load circuit 108 linearly decreases with the increase in temperature of the LED devices 101 and the drive current supplied to the LED devices 101 linearly increases with the increase in temperature of the LED devices 101.

With reference to FIG. 12, another specific example of a configuration of the analog circuit of the illuminating device 100 is described below. Explanation given below is based on an assumption that the detected voltage converted by the voltage conversion amplifier circuit 107 is further inverted and amplified by the electronic load circuit 108. Explanation already given with reference to FIG. 11 will be omitted as much as possible.

The analog circuit of the illuminating device 100 illustrated in FIG. 12 includes the LED devices 101, the thermistor 104, the constant current source 105, the op-amps (operation amplifiers) OP1 and OP2, the transistor Tr1 (or an FET), and a plurality of resistors R.

In this example, the electronic load circuit 108, which is described above, includes the op-amp OP2, the transistor Tr1, an electric-power input terminal for receiving a source voltage Vcc, and resistors R₅, R₆, R₈, R₉, R₁₀, and R₁₁.

The inverting input terminal (−) of the op-amp OP1 is connected to the electric-power input terminal for receiving the reference voltage V1 from the constant voltage source 110 (see FIG. 1), via the resistors R₁a and R₃, and is also connected to one end of the resistor R₄ via the resistor R₁a. The other end of the resistor R₄ is grounded.

The non-inverting input terminal (+) of the op-amp OP1 is connected to one end of the resistor R₂b that is set to have a resistance value equal to that of the resistor R₂a. The other end of the resistor R₂b is grounded. Furthermore, the non-inverting input terminal (+) of the op-amp OP1 is connected to the electric-power input terminal for receiving the reference voltage V1 from the constant voltage source 110 (see FIG. 1), via the resistance R₁b that is set to have a resistance value equal to that of the resistor R₁a, and the resistor R₀, and is also connected to one end of the resistor R_{T} of the thermistor 104 via the resistor R₁b. The other end of the resistor R_{T} is grounded.

The output terminal of the op-amp OP1 is connected to the inverting input terminal (−) of the op-amp OP1 via the resistor R₂a, and is also connected to the inverting input terminal (−) of the op-amp OP2 via the resistor R₈.

The inverting input terminal (−) of the op-amp OP2 is connected to the output terminal of the op-amp OP1 via the resistor R₈ as described above, and is also connected to the emitter of the transistor Tr1 via the resistor R₉.

The non-inverting input terminal (+) of the op-amp OP2 is connected to the electric-power input terminal for receiving the source voltage Vcc, via the resistor R₁₀, and is also connected to one end of the resistor R₁₁. The other end of the resistor R₁₁ is grounded.

The output terminal of the op-amp OP2 is connected to the base of the transistor Tr1 via the resistor R₅.

The collector of the transistor Tr1 is connected to the output terminal of the constant current source 105. The emitter of the transistor Tr1 is connected to the input terminal of the constant current source 105 via the resistor R₆, and is also connected to the inverting input terminal (−) of the op-amp OP2 via the resistor R₉ as described above. The base of the transistor Tr1 is connected to the output terminal of the op-amp OP2 via the resistor R₅ as described above.

In the analog circuit of the illuminating device 100 having the configuration as described above with reference to FIG. 12, when, for example, the temperature of the LED devices 101 increases, the resistance value of the resistor R_{T} linearly increases with the increase in temperature of the LED devices 101, so that the resistor divided voltage of the resistor R_{T} that divides the reference voltage V1 received from the constant voltage source 110, that is, the detected voltage, linearly increases with the increase in temperature of the LED devices 101. The detected voltage is input to the op-amp OP1, then inverted and amplified by the op-amp OP1, then amplified by the op-amp OP1, then output to the op-amp OP2, and then inverted and amplified by the op-amp OP2, so that the voltage that affects the base of the transistor Tr1 linearly decreases with the increase in temperature of the LED devices 101. Accordingly, the current that flows through the load of the electronic load circuit 108 linearly decreases with the increase in temperature of the LED devices 101 and the drive current supplied to the LED devices 101 linearly increases with the increase in temperature of the LED devices 101.

According to the illuminating device 100 of the present embodiment as described above, the drive current supplied to the LED devices 101 that emit light is changed linearly with the change in temperature of the LED devices 101 that is detected by the thermistor 104.

Furthermore, the illuminating device 100 of the present embodiment as described above includes the line sensor 3 having a plurality of pixels that are arrayed in the main-scanning direction and that convert light emitted from the illuminating device 100 and reflected from the original S to an electrical signal so as to read an image from the original S.

In this configuration, the illuminating device 100 and the image reading apparatus 1 use, as the detected amount, the change in temperature of the LED devices 101 that is detected by the thermistor 104, and linearly changes the drive current supplied to the LED devices 101 according to the change in temperature of the LED devices 101, so that it is possible to stabilize the light quantity of the LED devices 101 against the change in temperature. Therefore, it is possible to easily suppress the change in light quantity due to the change in temperature at, for example, the initial time after the LED devices 101 are turned on.

Furthermore, according to the illuminating device 100 and the image reading apparatus 1 of the present embodiment as described above, the substrate 103 on which the LED devices 101 are mounted in an array and to which the respective electrodes of the LED devices 101 are connected via the heat conductive members 114 in a heat conducting manner is provided, and the thermistor 104 detects the change in the temperature of the LED devices 101 via the heat conductive members 114 and the insulated heat conductive member 115 that is connected to the heat conductive members 114 in a heat-conducting and electrically-insulated manner. In this configuration, even when the illuminating device 100 and the image reading apparatus 1 include the plurality of LED devices 101, it is possible to detect the change in temperature of each LED device 101 by using the single thermistor 104. Therefore, it is possible to suppress the change in light quantity of the LED devices 101 inexpensively.

Moreover, according to the illuminating device 100 and the image reading apparatus 1 of the present embodiment as described above, the thermistor 104 may preferably include the resistor R_{T} that detects the detected amount of the change in temperature of the LED devices 101 according to a resistance value and that linearly changes the resistance value thereof according to the change in temperature of the LED devices 101. In this configuration, the illuminating device 100 and the image reading apparatus 1 realize the configuration where the drive current supplied to the LED devices 101 is changed linearly with the change in temperature of each of the LED devices 101 by using the analog circuit. As a result, it is possible to suppress the change in light quantity inexpensively.

Furthermore, the illuminating device 100 and the image reading apparatus 1 of the present embodiment as described above include the constant current source 105 that supplies the drive current to the LED devices 101, the voltage conversion amplifier circuit 107 that converts the detected amount obtained by the thermistor 104 to the detected voltage and amplifies the detected voltage, and the electronic load circuit 108 that divides the current received from the constant current source 105 that is connected parallel to the LED devices 101, and increases or decreases the current that flows through the load thereof according to the voltage amplified by the voltage conversion amplifier circuit 107. Here, the electronic load circuit 108 is preferably configured to decrease the current that flows through the load when the temperature of the LED devices 101 increases, and to increase the current that flows through the load when the temperature of the LED devices 101 decreases. In this configuration, the illuminating device 100 and the image reading apparatus 1 cause the voltage conversion amplifier circuit 107 to convert the detected amount received from the thermistor 104 to the detected voltage and amplify the detected voltage, decreases the current that flows through the load of the electronic load circuit 108 according to the amplified voltage when the temperature of the LED devices 101 increases, and increases the current that flows through the load of the electronic load circuit 108 according to the amplified voltage when the temperature of the LED devices 101 decreases. Therefore, it is possible to linearly change the drive current supplied to the LED devices 101 according to the change in temperature of the LED devices 101.

Moreover, according to the illuminating device 100 and the image reading apparatus 1 of the present embodiment as described above, the voltage conversion amplifier circuit 107 preferably includes the temperature-voltage conversion circuit 109 that converts the detected amount received from the thermistor 104 to the detected voltage, the constant voltage source 110 that outputs the reference voltage to the temperature-voltage conversion circuit 109, the offset-voltage regulator circuit 111 that adjusts the offset voltage to be lower than the detected voltage at the minimum operating temperature of the LED devices 101, and the differential amplifier 112 that amplifies the detected voltage based on the difference voltage between the detected voltage and the offset voltage. In this configuration, the illuminating device 100 and the image reading apparatus 1 are able to cancel the extra offset voltage of the output voltage that is received from the differential amplifier 112 of the voltage conversion amplifier circuit 107, and thus to increase the degree of amplification. Besides, when the change in temperature of the LED devices 101 is stabilized, the offset voltage output from the differential amplifier 112 becomes 0, so that the current that flows through the load of the electronic load circuit 108 becomes substantially 0 (zero), enabling to make the drive current supplied to the LED devices 101 substantially constant.

Moreover, in the illuminating device 100 and the image reading apparatus 1 of the present embodiment as described above, the voltage conversion amplifier circuit 107 is preferably configured such that the offset-voltage regulator circuit 111 shares the constant voltage source 110 and the voltage control unit 113 serving as means for controlling the voltage controls the voltage of the constant voltage source 110. In this configuration, the illuminating device 100 and the image reading apparatus 1 are able to appropriately adjust the offset voltage and the degree of amplification of the differential amplifier 112 depending on a situation by causing the voltage control unit 113 to adjust the voltage of the constant voltage source 110. Therefore, the voltage conversion amplifier circuit 107 is able to function as the temperature compensation circuit for the luminance of the LED devices 101, or the like, and it becomes possible to reduce the variation in luminance due to the surrounding temperature, light source atmosphere, and the like.

The illuminating device and the image reading apparatus according to the embodiment of the present invention as described above are not limited to those described in the above embodiments, and various modifications can be made without departing from the scope of the appended claims.

It has been explained that the illuminating device includes a plurality of LED devices; however it is not limited thereto, and the illuminating device may have at least one LED device. Furthermore, in the illuminating device, it is possible to form a linear light source by using, for example, a single LED device and a waveguide tube that guides illuminating light from the LED device in the main-scanning direction.

Moreover, it has been explained that the temperature detecting unit is a linear PTC thermistor; however it is not limited thereto.

Furthermore, it has been explained that the configuration, in which the drive current supplied to the LED devices is changed linearly with the change in temperature of the LED devices that is detected by the temperature detecting unit, is realized using the analog circuit; however, it is not limited thereto. For example, such a configuration may be realized using a digital circuit.

Moreover, it has been explained that the drive current supplied to the LED devices is linearly changed by linearly changing the current that flows through the electronic load unit according to the change in temperature; however, the drive current supplied to the LED devices may be linearly changed by linearly changing a current value of a constant current source without providing the electronic load unit.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An illuminating device, comprising:
an LED device configured to irradiate light;
a temperature detecting unit configured to detect a change in temperature of the LED device; and
a unit configured to linearly change a drive current supplied to the LED device according to the change in temperature of the LED device.

2. The illuminating device according to claim 1, further comprising:
a substrate on which an array of the LED devices are mounted and to which electrodes of the array of LED devices are connected heat-conductibly via a heat conductive member, wherein
the temperature detecting unit is configured to detect the change in temperature of the array of LED devices via the heat conductive member and an insulated heat conductive member that is connected heat-conductibly to the heat conductive member and electrically insulated.

3. The illuminating device according to claim 1, wherein the temperature detecting unit
includes a resistor having a resistance value that linearly changes according to the change in temperature of the LED device, and
is configured to obtain a detected amount of the change in temperature of the LED device according to the resistance value of the resistor.

4. The illuminating device according to claim 1, further comprising:
a constant current source configured to supply the drive current to the LED device;
a voltage converting and amplifying unit configured to convert the detected amount obtained by the temperature detecting unit to a detected voltage and to amplify the detected voltage; and
an electronic load unit that is connected to the constant current source in parallel with the LED device, and configured to divide a current from the constant current source and to change a current that flows through a load depending on the amplified detected voltage obtained by the voltage converting and amplifying unit, wherein
the electronic load unit decreases the current that flows through the load when the temperature of the LED device increases, and increases the current that flows through the load when the temperature of the LED device decreases.

5. The illuminating device according to claim 4, wherein the voltage converting and amplifying unit includes:
a temperature-voltage converting unit configured to convert the detected amount obtained by the temperature detecting unit to the detected voltage;
a constant voltage source configured to supply a reference voltage to the temperature-voltage converting unit;
an offset-voltage adjusting unit configured to adjust an offset voltage to be lower than the detected voltage at a minimum operating temperature of the LED device; and
an amplifying unit that amplifies the detected voltage based on a difference voltage between the detected voltage and the offset voltage.

6. The illuminating device according to claim 5, wherein
the offset-voltage adjusting unit shares the constant voltage source, and
the voltage converting and amplifying unit further includes a voltage control unit that controls a voltage of the constant voltage source.

7. An image reading apparatus comprising:
the illuminating device according to claim 1; and
a line sensor that includes a plurality of pixels that are arrayed in a main-scanning direction and that is configured to convert reflected light that has been emitted from the illuminating device and reflected from an illuminated object to an electrical signal to read an image from the illuminated object.
